(19) United States
(12) Patent Application Publication
(10) Pub. No.: US 2026/0280496 A1
(43) Pub. Date: Sep. 17, 2026

(54) HIGH LINEARITY TRANSCONDUCTANCE AMPLIFIER

(71) Applicant: Realtek Semiconductor Corporation, Hsinchu (TW)

(72) Inventor: Hao-Cheng HSU, Hsinchu (TW)

(21) Appl. No.: 19/287,852

(22) Filed: Aug. 1, 2025

(30) Foreign Application Priority Data
Mar. 11, 2025 (TW) 114108967

(51) Int. Cl. H03F 1/32; H03F 3/45

(52) U.S. Cl. CPC H03F 1/3211; H03F 3/45183

(57) ABSTRACT

A high linearity transconductance amplifier includes a first transistor, a second transistor, two source resistors, a load, a common mode voltage (VCM) calibration device, and a VCM calibration circuit. The first and second transistors generate a pair of output currents to the load. The source resistors are coupled in series between source electrodes of the first and second transistors. The source electrodes of the first and second transistors have a first source voltage and a second source voltage respectively. The VCM calibration circuit compares an input common mode voltage with a reference voltage and counts based on the comparing result, thereby adjusting the input common mode voltage related to the first and second source voltages. The VCM calibration device provides a bias voltage to the load according to a system high voltage and the counting result of the VCM calibration circuit.

### CROSS-REFERENCE TO RELATED APPLICATION

This application claims priority to Taiwan Application Serial Number 114108967, filed Mar. 11, 2025, which is herein incorporated by reference in its entirety.

### BACKGROUND

### Field of Invention

The present disclosure relates to a transconductance amplifier. More particularly, the present disclosure relates to a high linearity transconductance amplifier.

### Description of Related Art

A transconductance amplifier receives a voltage signal to output a current signal. Ideally, an incremental change of the voltage signal will cause an equally proportional incremental change of the current signal. When the incremental change of the current signal is not completely proportional to the incremental change of the voltage signal, non-ideal characteristics (also called non-linearity) will appear. Although various methods have been proposed in the known technologies to improve the linearity of the transconductance amplifier, such as a source degeneration technology, a cross-coupled multiple differential-input technology, and a gm-boosting technology based on a cascode circuit, these methods are not conducive to high-speed circuit applications or have the problem of insufficient voltage headroom.

### SUMMARY

The present disclosure provides a high linearity transconductance amplifier including a differential pair, two source resistors, a load, a common mode voltage (VCM) calibration circuit. The differential pair receives a pair of input voltages to generate a pair of output currents. The differential pair includes a first transistor and a second transistor. The source resistors are coupled in series between a source electrode of the first transistor and a source electrode of the second transistor. The source electrode of the first transistor has a first source voltage and the source electrode of the second transistor has a second source voltage. The load is coupled to the differential pair to receive the pair of output currents. The VCM calibration circuit compares an input common mode voltage with a reference voltage to generate a comparing result. The VCM calibration circuit further counts based on the comparing result, thereby adjusting the input common mode voltage related to the first and second source voltages.

The present disclosure further provides a high linearity transconductance amplifier including a first transistor, a second transistor, two source resistors, a load, a VCM calibration device, and a VCM calibration circuit. The first transistor receives a first input voltage to generate a first output current. The second transistor receives a second input voltage to generate a second output current. The first transistor and the second transistor form a differential pair. The source resistors are coupled in series between a source electrode of the first transistor and a source electrode of the second transistor. The source electrode of the first transistor has a first source voltage and the source electrode of the second transistor has a second source voltage. The load is coupled to the differential pair to receive the first output current and the second output current. The VCM calibration device is coupled to the load and biased under a system high voltage, thereby providing a bias voltage to the load. The VCM calibration circuit compares an input common mode voltage with a reference voltage to generate a comparing result. The VCM calibration device provides the bias voltage according to the comparing result. The input common mode voltage is related to the first source voltage and the second source voltage.

In order to make the above features and advantages of the present disclosure more apparent and understandable, the following embodiments of the present disclosure, together with the accompanying drawings, are described in detail below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a system block diagram of a high linearity transconductance amplifier according to some embodiments of the present disclosure.

FIG. 2 is a circuit diagram of an input common mode voltage generating circuit according to some embodiments of the present disclosure.

FIG. 3 is a circuit diagram of the VCM calibration device according to another embodiment of the present disclosure.

FIG. 4 and FIG. 5 are utilized to illustrate how the high linearity transconductance amplifier of the present disclosure improves linearity.

### DETAILED DESCRIPTION

Specific embodiments of the present disclosure are further described in detail below with reference to the accompanying drawings. However, the embodiments described are not intended to limit the present disclosure and it is not intended for the description of operations to limit the order of implementation. The terms “first” and “second” used in the specification should be understood as identifying units or data described by the same terminology, and do not refer to a particular order or sequence.

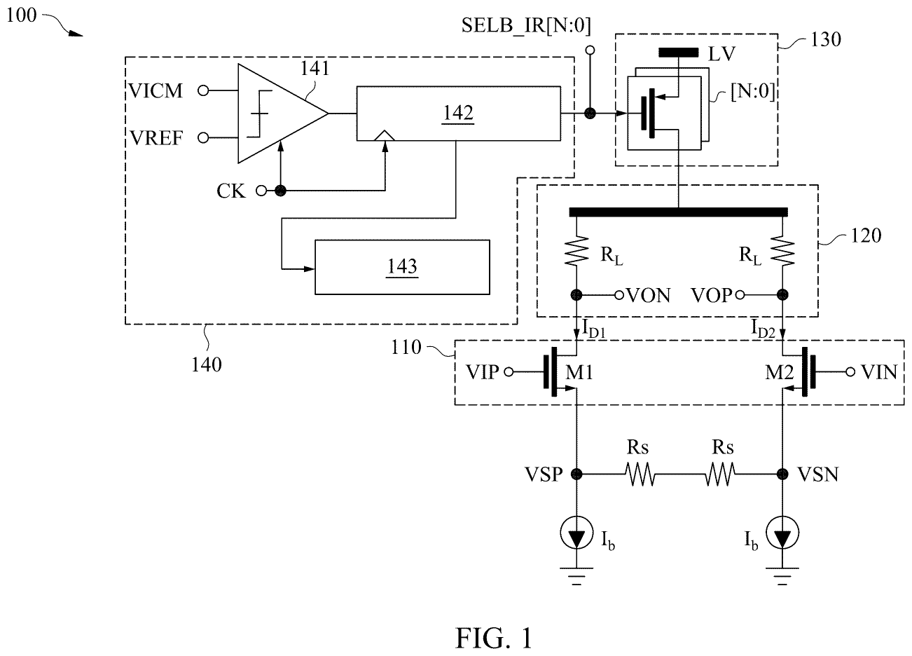

FIG. 1 is a system block diagram of a high linearity transconductance amplifier 100 according to some embodiments of the present disclosure. The high linearity transconductance amplifier 100 includes a first transistor M1, a second transistor M2, two source resistors Rs, a load 120, a common mode voltage (VCM) calibration device 130, and a VCM calibration circuit 140. The first transistor M1 and the second transistor M2 form a differential pair 110.

The first transistor M1 receives the first input voltage VIP to generate a first output current I_{D1}. The second transistor M2 receives the second input voltage VIN to generate a second output current I_{D2}. In other words, the differential pair 110 receive a pair of input voltages (i.e., the first input voltage VIP and the second input voltage VIN) to generate a pair of output currents (i.e., the first output current I_{D1} and the second output current I_{D2}).

The load 120 is coupled to the differential pair 110 (i.e., the first transistor M1 and the second transistor M2) to receive the pair of output currents (i.e., the first output current I_{D1} and the second output current I_{D2}). In other words, the differential pair 110 (i.e., the first transistor M1 and the second transistor M2) generates the pair of output currents to the load 120. In detail, the load 120 includes two load resistors R_{L}. One terminal of one of two load resistors R_{L} is coupled to one terminal of the other of two load resistors R_{L}. The other terminal of one of two load resistors R_{L} is coupled to a drain electrode of the first transistor M1 to receive the first output current I_{D1}. The other terminal of the other of two load resistors R_{L} is coupled to a drain electrode of the second transistor M2 to receive the second output current I_{D2}.

The drain electrode of the first transistor M1 has a first output voltage VON. The drain electrode of the second transistor M2 has a second output voltage VOP. Specifically, the pair of input voltages (i.e., the first input voltage VIP and the second input voltage VIN) are converted into the output voltage of the differential pair 110 (i.e., the difference between the first output voltage VON and the second output voltage VOP) through the differential pair 110 and the load 120.

Two source resistors Rs are coupled in series between a source electrode of the first transistor M1 and a source electrode of the second transistor M2. The source electrode of the first transistor M1 has a first source voltage VSP. The source electrode of the second transistor M2 has a second source voltage VSN. Specifically, two source resistors Rs are served as a degeneration resistor to improve linearity and control a gain of the differential pair 110.

The high linearity transconductance amplifier 100 further includes two current sources I_{b}. One of two current sources I_{b} is coupled between the source electrode of the first transistor M1 and a ground terminal. The other of two current sources I_{b} is coupled between the source electrode of the second transistor M2 and the ground terminal.

The VCM calibration circuit 140 includes a comparator 141, a counter 142, and an input common mode voltage generating circuit 143. The comparator 141 compares an input common mode voltage VICM with a reference voltage VREF to generate a comparing result. In detail, the comparator 141 compares the input common mode voltage VICM with the reference voltage VREF based on a clock signal CK. The counter 142 is coupled to the comparator 141. The counter 142 counts based on the comparing result generated by the comparator 141, thereby generating a counting result. Specifically, the counter 142 counts based on the clock signal CK.

The input common mode voltage generating circuit 143 is coupled to the counter 142. The input common mode voltage generating circuit 143 adjusts the input common mode voltage VICM according to the counting result generated by the counter 142. In other words, the VCM calibration circuit 140 compares the input common mode voltage VICM with the reference voltage VREF to count according to the comparing result, thereby adjusting the input common mode voltage VICM.

In some embodiments of the present disclosure, the input common mode voltage VICM is related to the first source voltage VSP and the second source voltage VSN. For example, the input common mode voltage VICM=(the first input voltage VIP+the second input voltage VIN)/2, and the first input voltage VIP=the first source voltage VSP+a gate-source voltage (VGS) of the first transistor M1, and the second input voltage VIN=the second source voltage VSN+a gate-source voltage (VGS) of the second transistor M2.

It is worth mentioning that the present disclosure does not limit the implementation of the VCM calibration circuit 140. Any circuit that can obtain the input common mode voltage VICM according to the first source voltage VSP and the second source voltage VSN and feedback the relationship between the input common mode voltage VICM and the reference voltage VREF to the VCM calibration device 130 may be used to implement the VCM calibration circuit 140.

The VCM calibration device 130 is coupled between the VCM calibration circuit 140 and the load 120 and is biased to the system high voltage LV. The VCM calibration device 130 provides a bias voltage to the load 120 according to the system high voltage LV and the counting result generated by the counter 142 of the VCM calibration circuit 140, thereby adjusting the first output voltage VON and the second output voltage VOP. In other words, the present disclosure feedbacks the counting result of the VCM calibration circuit 140 to the VCM calibration device 130 to adjust the first output voltage VON and the second output voltage VOP.

As shown in FIG. 1, the VCM calibration device 130 includes plural transistor switches [N:0] (i.e., N transistor switches). A gate electrode of each transistor switch receives the counting result of the counter 142 of the VCM calibration circuit 140. A source electrode of each transistor switch receives the system high voltage LV. A drain electrode of each transistor switch provides the bias voltage to the load 120. Specifically, the counter 142 determines whether a value temporarily stored in the counter 142 is added by +1 or −1 based on the comparing result generated by the comparator 141, and the counting result generated by the counter 142 is a digital signal (i.e., SELB_IR[N:0] as labelled in FIG. 1), and the counting unit of the digital signal is the number of bits. In other words, the present disclosure gradually adjusts the input common mode voltage VICM, the first output voltage VON, and the second output voltage VOP through the VCM calibration circuit 140 and the VCM calibration device 130, thereby achieving the purpose of improving linearity.

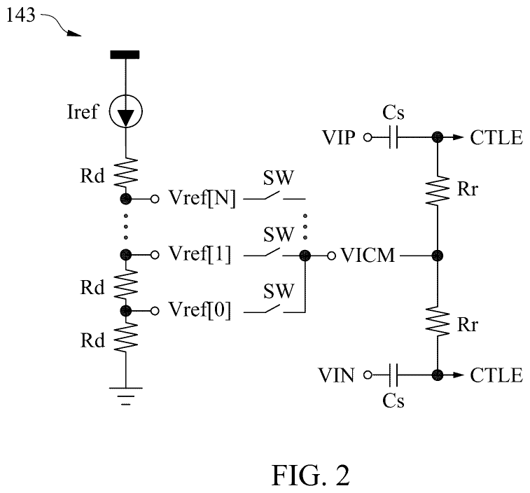

FIG. 2 is a circuit diagram of an input common mode voltage generating circuit 143 according to some embodiments of the present disclosure. The input common mode voltage generating circuit 143 includes a current source Iref, plural resistors Rd, and plural switches SW. The resistors Rd are coupled in series to the current source Iref. The current source Iref generates a current flowing through the resistors Rd, thereby providing plural reference voltage values Vref[N], . . . , Vref[1], Vref[0] by a voltage-dividing manner using voltage-dividing resistors (i.e., the resistors Rd).

One terminal of each switch SW is coupled between two adjacent resistors Rd and has one of the reference voltage values Vref[N], . . . , Vref[1], Vref[0]. The other terminal of each switch SW provides the input common mode voltage VICM. The switches SW are controlled by the digital signal (i.e., corresponding to the counting result) generated by the counter 142, and the input common mode voltage generating circuit 143 turns on one of the switches SW according to the digital signal (i.e., corresponding to the counting result), such that the input common mode voltage VICM is equal to one of the reference voltage values Vref[N], . . . , Vref[1], Vref[0].

In other words, the input common mode voltage generating circuit 143 selects one of the reference voltage values Vref[N], . . . , Vref[1], Vref[0] as the input common mode voltage VICM according to the counting result of the counter 142. Specifically, the input common mode voltage generating circuit 143 utilizes the current source Iref to generate the current flowing through the resistors Rd so as to obtain the reference voltage values by the voltage-dividing manner using voltage-dividing resistors (i.e., the resistors Rd), thereby controlling the switches SW to obtain the input common mode voltage VICM.

When the input common mode voltage generating circuit 143 adjusts the input common mode voltage VICM according to the counting result of the counter 142, the pair of input voltages (i.e., the first input voltage VIP and the second input voltage VIN) received by the differential pair 110 is also adjusted accordingly. As shown in FIG. 2, a capacitor Cs and a resistor Rr are coupled in series between a node corresponding to the first input voltage VIP and a node corresponding to the input common mode voltage VICM. A capacitor Cs and a resistor Rr are coupled in series between a node corresponding to the second input voltage VIN and the node corresponding to the input common mode voltage VICM. A node between the capacitor Cs and the resistor Rr is further coupled to a continuous-time linear equalizer (CTLE).

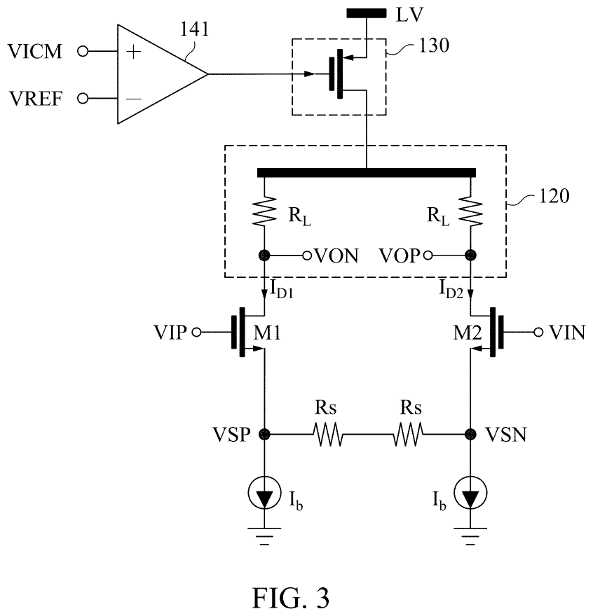

In the embodiment as shown in FIG. 1, the VCM calibration device 130 is a switch circuit (including plural transistor switches [N:0]) controlled by the digital signal (i.e., SELB_IR[N:0] as labelled in FIG. 1). However, in another embodiment of the present disclosure, the VCM calibration device 130 is a bias device controlled by an analog signal. FIG. 3 is a circuit diagram of the VCM calibration device 130 according to another embodiment of the present disclosure. As shown in FIG. 3, the VCM calibration device 130 is coupled between the comparator 141 and the load 120 and is biased under the system high voltage LV. The VCM calibration device 130 provides the bias voltage to the load 120 according to the comparing result between the system high voltage LV and the comparator 141. As shown in FIG. 3, the VCM calibration device 130 includes a transistor switch. A gate electrode of the transistor switch receives the comparing result of the comparator 141, a source electrode of the transistor switch receives the system high voltage LV, and a drain electrode of the transistor switch provides the bias voltage to the load 120. In other words, the VCM calibration device 130 is a bias device controlled by an analog signal (i.e., corresponding to the comparing result of the comparator 141).

It is worth mentioning that the VCM calibration device 130 is utilized to adjust the input common mode voltage of the next stage amplifier. Therefore, if there is no next stage amplifier, the VCM calibration device 130 can be omitted (i.e., one terminal of one of two load resistors R_{L} of the load 120 is coupled to one terminal of the other of two load resistors R_{L} of the load 120 so as to receive the system high voltage LV), and only the VCM calibration circuit 140 is required for adjusting the input common mode voltage VICM of this stage amplifier.

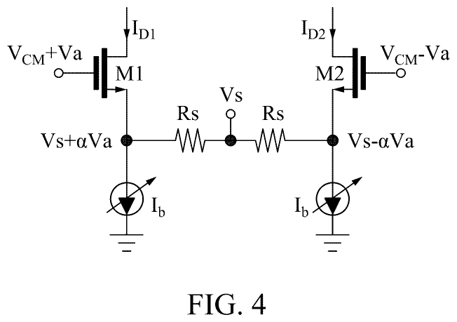

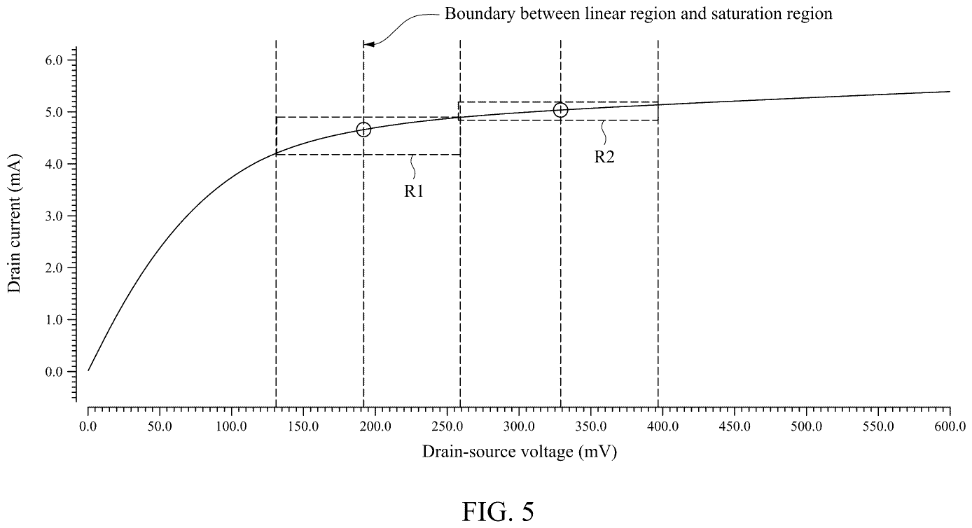

Next, FIG. 4 and FIG. 5 are utilized to illustrate how the high linearity transconductance amplifier of the present disclosure improves linearity. In the differential pair circuit with degeneration resistor as shown in FIG. 4, the first input voltage VIP and the second input voltage VIN are represented as VCM+Va and VCM−Va, respectively. In other words, Va is an input voltage swing of the differential pair. The first source voltage VSP and the second source voltage VSN are represented as Vs+αVa and Vs−αVa, respectively. In other words, α (which is a value less than 1) is a gain of a source follower, and Vs is the voltage of the node between the two source resistors Rs. According to the transistor current formula, an output differential current of the differential pair is shown in the following equation (1):

$${I}_{D 1} - {I}_{D 2} = μ {C}_{o x} \frac{W}{L} \cdot {V}_{a} \cdot ( 1 - α ) \cdot \sqrt{\frac{4 \cdot {I}_{SS}}{μ {C}_{ox} \frac{W}{L}} - 4 {( 1 - α )}^{2} {V}_{a}^{2}} , \qquad ( 1 )$$

where μ is the mobility of the transistor, Cₒₓ is the oxide capacitance of the gate electrode of the transistor, W and L are the width and the length of the gate electrode of the transistor, respectively, and I_{SS} is the steady-state current of the transistor.

According to the equation (1), if α is not considered, when the input voltage swing Va is not a very small value, the function in the equation (1) is not linearly proportional to Va, resulting in the nonlinearity of the differential pair. Therefore, generally speaking, when 4·I_{S}s/(μCₒₓ W/L)>>4Va², that is, when the overdrive voltage (Vov)/\sqrt{2}>>Va, the function in the equation (1) can be regarded as a linear function. Therefore, increasing the overdrive voltage can increase the linearity of the differential pair.

Next, as shown in FIG. 5, when the differential pair is biased in a region R2, the drain-source voltage of the transistor is sufficient (i.e., the general design). At this time, the total current (i.e., the nominal bias current) of the differential pair is approximately (id+Δi)+ (id−Δi)=2×id, which means that the total current (i.e., the nominal bias current) of the differential pair has not changed. Therefore, the output differential current of the differential pair is still determined by the equation (1), and the linearity has not changed relative to the ideal differential pair.

As shown in FIG. 5, when the differential pair is biased in a region R1, the drain-source voltage of the transistor is insufficient. At this time, the total current (i.e., the nominal bias current) of the differential pair is approximately (id+Δi1)+ (id−Δi2) and Δi1<Δi2. Therefore, the negative terminal current of the differential pair begins to decrease when the input voltage swing reaches a certain level, that is, I_{D1}-I_{D2}=2×id+ (Δi2−Δi1). Accordingly, the output differential current of the differential pair increases instead, thereby compensating the output differential current that was originally about to enter saturation.

In addition, FIG. 5 shows an I-V (the drain current of the transistor versus the drain-source voltage) characteristic curve of the transistor. The differentiation of the characteristic curve is the inverse of the output impedance (rₒᵤₜ) of the current source. Therefore, it can be seen from FIG. 5 that when the bias point of the first source voltage VSP or the second source voltage VSN is above 200 mV, the output impedance (rₒᵤₜ) of the current source will not be affected by the change of the first source voltage VSP or the second source voltage VSN. However, when the bias point of the first source voltage VSP or the second source voltage VSN is below 200 mV, the output impedance (rₒᵤₜ) of the current source varies in response to changes in the first source voltage VSP or the second source voltage VSN, with the effect becoming more pronounced as the voltage decreases.

As shown in FIG. 4 and FIG. 5, in the DC-signal analysis, when the input voltage swing Va increases, as described above with respect to the equation (1), the function in the equation (1) is not linearly proportional to Va. As shown in the I-V characteristic curve of FIG. 5, when the input voltage swing widens, the I-V characteristic curve begins to enter saturation. At this time, taking the I-V characteristic curve of FIG. 5 as an example, if the bias point of the first source voltage VSP or the second source voltage VSN is biased near 200 mV (approximately at the boundary between the linear region and the saturation region of the transistor), a decrease in the second source voltage VSN will reduce the output impedance (rₒᵤₜ) of the current source. This reduced output impedance forms a parallel combination with the source resistance Rs, resulting in an overall lower impedance. Therefore, equivalently, the source-degenerated differential transconductance (i.e., the differential gm) is boosted back, such that the saturated current difference can be widened.

This phenomenon occurs when the input voltage swing widens and the differential transconductance (i.e., the differential gm) begins to decay. The boosted differential transconductance (i.e., the differential gm) will further widen the current difference at the output terminal, and equivalently, the linear range becomes wider.

To sum up, the present disclosure provides a high linearity transconductance amplifier adjustment architecture, which monitors the input common mode voltage VICM (i.e., compares the input common mode voltage VICM with the reference voltage VREF, and the value of the reference voltage VREF is approximately the drain-source voltage of the first transistor M1 and/or the second transistor M2 at the boundary of the linear region and the saturation region of the first transistor M1 and/or the second transistor M2), thereby adjusting the input common mode voltage VICM and the bias voltage of the output terminal. As a result, the bias points of the first source voltage VSP and the second source voltage VSN are shifted, thereby enabling a bias condition significantly alters the output impedance (rₒᵤₜ) of the current source under larger input voltage swings to improve linearity.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A high linearity transconductance amplifier, comprising:
a differential pair configured to receive a pair of input voltages to generate a pair of output currents, wherein the differential pair comprises a first transistor and a second transistor;
two source resistors coupled in series between a source electrode of the first transistor and a source electrode of the second transistor, wherein the source electrode of the first transistor has a first source voltage and the source electrode of the second transistor has a second source voltage;
a load coupled to the differential pair to receive the pair of output currents; and
a common mode voltage (VCM) calibration circuit configured to compare an input common mode voltage with a reference voltage to generate a comparing result, wherein the VCM calibration circuit is further configured to count based on the comparing result, thereby adjusting the input common mode voltage related to the first source voltage and the second source voltage.

2. The high linearity transconductance amplifier of claim 1, wherein a value of the reference voltage is approximately a drain-source voltage at a boundary between a linear region and a saturation region of the first transistor or the second transistor.

3. The high linearity transconductance amplifier of claim 1, wherein the VCM calibration circuit comprises:
a comparator configured to compare the input common mode voltage with the reference voltage to generate the comparing result; and
a counter coupled to the comparator to count based on the comparing result, thereby generating a counting result.

4. The high linearity transconductance amplifier of claim 3, wherein the comparator compares the input common mode voltage with the reference voltage based on a clock signal, wherein the counter counts based on the clock signal.

5. The high linearity transconductance amplifier of claim 3, wherein the VCM calibration circuit further comprises:
an input common mode voltage generating circuit coupled to the counter to select one of a plurality of reference voltage values as the input common mode voltage according to the counting result.

6. The high linearity transconductance amplifier of claim 5, wherein the input common mode voltage generating circuit comprises:
a current source configured to generate a current;
a plurality of resistors coupled in series to the current source; and
a plurality of switches;
wherein the input common mode voltage generating circuit turns on one of the switches according to the counting result, wherein one terminal of each of the switches is coupled between two adjacent ones of the resistors and has one of the reference voltage values, and the other terminal of each of the switches provides the input common mode voltage.

7. The high linearity transconductance amplifier of claim 3, further comprising:
a VCM calibration device coupled between the comparator and the load and biased under a system high voltage, wherein the VCM calibration device provides a bias voltage to the load according to the system high voltage and the comparing result.

8. The high linearity transconductance amplifier of claim 7, wherein the VCM calibration device comprises a transistor switch, wherein the transistor switch comprises:
a gate electrode configured to receive the comparing result;
a source electrode configured to receive the system high voltage; and
a drain electrode configured to provide the bias voltage to the load.

9. The high linearity transconductance amplifier of claim 1, further comprising:
a VCM calibration device coupled between the VCM calibration circuit and the load and biased under a system high voltage, thereby providing a bias voltage to the load according to the system high voltage and the comparing result.

10. The high linearity transconductance amplifier of claim 9, wherein the VCM calibration device comprises a plurality of transistor switches, wherein each of the transistor switches comprises:
a gate electrode configured to receive the comparing result;
a source electrode configured to receive the system high voltage; and
a drain electrode configured to provide the bias voltage to the load.

11. A high linearity transconductance amplifier, comprising:
a first transistor configured to receive a first input voltage to generate a first output current;
a second transistor configured to receive a second input voltage to generate a second output current, wherein the first transistor and the second transistor form a differential pair;
two source resistors coupled in series between a source electrode of the first transistor and a source electrode of the second transistor, wherein the source electrode of the first transistor has a first source voltage and the source electrode of the second transistor has a second source voltage;
a load coupled to the differential pair to receive the first output current and the second output current;
a VCM calibration device coupled to the load and biased under a system high voltage, thereby providing a bias voltage to the load; and
a VCM calibration circuit configured to compare an input common mode voltage with a reference voltage to generate a comparing result;
wherein the VCM calibration device is configured to provide the bias voltage according to the comparing result, wherein the input common mode voltage is related to the first source voltage and the second source voltage.

12. The high linearity transconductance amplifier of claim 11, wherein a value of the reference voltage is approximately a drain-source voltage at a boundary between a linear region and a saturation region of the first transistor or the second transistor.

13. The high linearity transconductance amplifier of claim 11, wherein the VCM calibration circuit further counts based on the comparing result, thereby adjusting the input common mode voltage.

14. The high linearity transconductance amplifier of claim 13, wherein the VCM calibration circuit comprises:
a comparator configured to compare the input common mode voltage with the reference voltage to generate the comparing result; and
a counter coupled to the comparator and configured to count based on the comparing result to generate a counting result.

15. The high linearity transconductance amplifier of claim 14, wherein the comparator compares the input common mode voltage with the reference voltage based on a clock signal, wherein the counter counts based on the clock signal.

16. The high linearity transconductance amplifier of claim 14, wherein the VCM calibration circuit further comprises:
an input common mode voltage generating circuit coupled to the counter and configured to select one of a plurality of reference voltage values as the input common mode voltage according to the counting result.

17. The high linearity transconductance amplifier of claim 16, wherein the input common mode voltage generating circuit comprises:
a current source configured to generate a current;
a plurality of resistors coupled in series to the current source; and
a plurality of switches;
wherein the input common mode voltage generating circuit turns on one of the switches according to the counting result, wherein one terminal of each of the switches is coupled between two adjacent ones of the resistors and has one of the reference voltage values, and the other terminal of each of the switches provides the input common mode voltage.

18. The high linearity transconductance amplifier of claim 11, wherein the VCM calibration device is coupled between the VCM calibration circuit and the load and provides the bias voltage to the load according to the system high voltage and the comparing result.

19. The high linearity transconductance amplifier of claim 18, wherein the VCM calibration device comprises a plurality of transistor switches, wherein each of the transistor switches comprises:
a gate electrode configured to receive the comparing result;
a source electrode configured to receive the system high voltage; and
a drain electrode configured to provide the bias voltage to the load.

20. The high linearity transconductance amplifier of claim 19, wherein the VCM calibration device comprises a transistor switch, wherein the transistor switch comprises:
a gate electrode configured to receive the comparing result;
a source electrode configured to receive the system high voltage; and
a drain electrode configured to provide the bias voltage to the load.
